(19) United States
(12) Patent Application Publication
(10) Pub. No.: US 2023/0081784 A1
(43) Pub. Date: Mar. 16, 2023

(54) RESISTOR ARRANGEMENT

(71) Applicant: Wieland-Werke AG, Ulm (DE)

(72) Inventors: Tony Robert NOLL, Dietenheim (DE); Gerhard THUMM, Erbach (DE); Christoph KÄSTLE, Ulm (DE); Jochen WALLISER, Ulm (DE); Felix SCHULZ, Ulm (DE)

(21) Appl. No.: 17/932,335

(22) Filed: Sep. 15, 2022

(30) Foreign Application Priority Data
Sep. 16, 2021 (DE) 102021004687.0

(51) Int. Cl. H01C 1/14; G01R 15/14

(52) U.S. Cl. CPC H01C 1/14; G01R 15/146

(57) ABSTRACT

A resistor arrangement for measuring current strength having connection elements and a resistor element between the connection elements. The connection elements and the resistor element are arranged in a plane and in a row such that the arrangement is strip-shaped and has its smallest spatial extent perpendicular to the current direction. The resistor element has two contact sides and the connection elements each have a contact face connected to the contact sides. When current flows through the arrangement, current flow lines are formed which are deflected at at least one of the contact sides by an angle of at least 5° at the transition from the connection element to the resistor element.

### CROSS-REFERENCE TO RELATED APPLICATION

This claims priority from German Application No. 10 2021 004 687.0, filed Sep. 16, 2021, the disclosure of which is hereby incorporated by reference in its entirety.

### TECHNICAL FIELD

The invention relates to a resistor arrangement for measuring the strength of an electric current.

### BACKGROUND AND SUMMARY

For current measurement in electronic circuits, measuring resistors are used which are connected in series to the component to be monitored. The current strength is determined here according to Ohm's law from the voltage dropping across the measuring resistor, which is referred to as a shunt resistor. The size of the resistor is assumed to be known. Correct and reliable measurement of the current strength is particularly important in a battery management system of an electric or hybrid vehicle, for example. A resistor arrangement comprising such a low-resistance measuring resistor with approximately 10 to 50 μOhm as well as connection elements for connecting the resistor arrangement to the circuit can be made produced from a longitudinally welded composite material. This is known, for example, from the publication EP 0 605 800 A1. The composite material is produced from three metal strips by joining the individual metal strips to one another, in each case via a longitudinal seam, by an electron beam or laser welding process. The middle metal strip consists here of a material with a very low temperature coefficient of resistance. This material forms the actual resistor element of the measuring resistor. The two outer bands are usually made of a material with high electrical conductivity, for example copper. Such materials usually have a large temperature coefficient of resistance compared to the material of the resistor element. These two outer bands are used to form connection elements via which the measuring resistor can be connected to a circuit.

Determining the current strength from the voltage dropping across the measuring resistor requires precise knowledge of the resistance value. The influence of temperature on the resistivity of the materials used plays an important role here. Usually, the voltage taps on the connection elements are positioned at a distance from the resistor element, so that the measured voltage contains not only the voltage drop across the resistor element, but also contributions resulting from the voltage drop across a part of the connection elements in each case. These contributions vary with temperature and may thus falsify the determination of the current strength.

From the publications EP 2 446 449 B1 and WO 2011/028 870 A1, resistor arrangements are known in which the distribution of the electrical potential is changed by slots in such a way that the influence of the temperature on the determination of the current strength is minimized.

It is the object of the invention to provide an alternative resistor arrangement for determining the strength of an electric current flowing through the resistor arrangement, in which the influence of temperature on the determination of the current strength is reduced.

The invention is represented by the features of claim 1. The further, dependent claims relate to advantageous embodiments and developments of the invention.

The invention relates to a resistor arrangement for measuring the strength of an electric current flowing through the resistor arrangement substantially in an externally determinable direction. The resistor arrangement comprises at least two strip- or plate-shaped connection elements for connecting the resistor arrangement to an external circuit and at least one strip- or plate-shaped resistor element arranged between the connection elements with respect to the direction of the current. The connection elements and the resistor element for forming the resistor arrangement are arranged in a plane next to each other and in a row with respect to each other in such a way that the resistor arrangement has the form of a strip and has its smallest spatial extent in a direction oriented perpendicular to the direction of the electric current. The at least one resistor element consists of a material of which the electrical resistivity at room temperature is greater by at least a factor of 10 than the electrical resistivity of the material of the connection elements. The at least one resistor element has two contact sides parallel to each other. The connection elements each have a contact face at which they are connected to one of the contact sides of the at least one resistor element or of a further resistor element directly or indirectly via a transition zone and are in electrical contact. According to the invention, the at least one resistor element is arranged in such a way that, when current flows through the resistor arrangement, current flow lines are formed which are deflected at at least one of the contact sides of the resistor element by an angle of at least 5°, averaged over the entire contact face, at the transition from the connection element to the resistor element, this deflection taking place in a plane which is perpendicular to the direction of the smallest spatial extent of the resistor arrangement.

The resistor arrangement described above may comprise a shunt resistor with a resistance of from 10 to 100 μOhm as the resistor element. Both the resistor element and the connection elements consist of electrically conductive materials. In this case, the electrical resistivity of the material of the resistor element is greater than the electrical resistivity of the material of the connection elements by at least a factor of 10. On the other hand, the temperature coefficient of resistance of the material of the connection elements is much greater, typically greater than the value of the temperature coefficient of resistance of the material of the resistor element by at least a factor of 80. Typically, the strength of the temperature coefficient of resistance of the material of the resistor element is less than 5·10⁻⁵ l/K, while the temperature coefficient of resistance of the material of the connection elements is about 4·10⁻³ l/K. In particular, the connection elements of the resistor arrangement may be made of copper, a preferably low-alloy copper alloy, aluminum, or a preferably low-alloy aluminum alloy, or may comprise at least one of these materials. The resistor element may be made of a copper alloy commonly used as a resistor alloy or of steel.

By means of the connection elements, the resistor arrangement can be connected to an external circuit. The direction of the current in the resistor arrangement can be substantially defined by the connection elements. The connection elements of the resistor arrangement may be terminal connection elements. However, it is also possible that at least one connection element is arranged between two resistor elements with respect to a possible current path.

The resistor arrangement is formed in a planar arrangement. Here, the connection elements and the at least one resistor element are formed as plate-shaped or strip-shaped elements and are arranged in a plane next to each other and in a row. A plate- or strip-shaped body has at least two sides parallel to each other. Further, a plate- or strip-shaped body, in the spatial direction that is perpendicular to the mutually parallel sides, typically has an extent that is smaller, in most cases significantly smaller, than the extent of the body in the other two spatial directions. The extent of the body in this direction is referred to as the thickness of the plate- or strip-shaped body. The thickness of the resistor element(s) can be arbitrary. Usually, however, it is not greater than the thickness of the connection elements.

The connection elements and the resistor element are arranged in a plane next to each other and in a row with respect to each other, so that the resistor arrangement itself can again form a substantially strip-shaped composite body. The resistor arrangement thus has an extent in one spatial direction that is significantly smaller than the spatial extent of the resistor arrangement in the two other spatial directions. The direction of the smallest spatial extent of the resistor arrangement is perpendicular to the direction of the electric current.

The resistor element has two contact sides, on each of which it is connected to a connection element directly or indirectly via a transition zone and is in electrical contact with the latter. The connection can be realized by a weld seam, so that there is a spatially extended metallurgical transition region formed as a weld zone between the materials in each case. The two contact sides of the resistor element are parallel to each other and can preferably have the shape of a rectangle.

When current flows through the resistor arrangement, areas of constant electrical potential are formed in the resistor arrangement, and the lines of intersection of said areas with the area of the resistor arrangement are called equipotential lines. The electric current flows perpendicularly to the areas of constant potential or perpendicularly to the equipotential lines. The path of the current can be represented by current flow lines. The current flows through the resistor element in such a way that the lowest voltage drop across the resistor arrangement occurs for a given current strength. In the resistor element, the current flow lines are therefore formed in such a way that they are oriented perpendicularly or at least almost perpendicularly to the two parallel contact sides of the resistor element, except for edge regions. The current flow lines are inclined at most by a small angle with respect to the contact sides of the resistor element.

If the resistor element is arranged in the resistor arrangement in such a way that the current flow lines on at least one of the contact sides of the resistor element are deflected by a significant angle at the transition from the connection element to the resistor element, then the current flow lines in this connection element do not run perpendicularly towards the resistor element but are inclined at an angle. The angle by which the current flow lines are deflected depends on the angle at which the current flow lines in the connection element run toward the resistor element, as well as on the ratio of the resistivity of the material of the resistor element and the connection element. Typically, this ratio is between 20 and 30. Because the current flow lines in the connection element are not perpendicular to the resistor element, the equipotential lines perpendicular to the current flow lines are not parallel to the contact sides of the resistor element, but are inclined by an angle approximately equal to the angle by which the current flow lines are deflected. Therefore, there are equipotential lines in the connection element that intersect the contact sides of the resistor element at an angle. On these equipotential lines, the electrical potential prevailing at a point of the contact face between the connection element and the resistor element can thus be tapped in the connection element. This thus opens up the advantageous possibility of positioning a voltage tap in the region of the connection element at a distance from the resistor element and of still tapping the electrical potential at the contact face between the connection element and the resistor element. The influence of the resistivity of the material of the connection element on the measured value is reduced in this way.

If the temperature of the resistor arrangement changes, then the resistivities of the connection element and of the resistor element also change. The change in the resistivity of the connection element is significantly greater than the change in the resistivity of the resistor element. As the resistances change with temperature, the equipotential lines in the resistor arrangement shift. However, the equipotential lines that intersect the contact sides of the resistor element shift very little because their electrical potential is virtually fixed to the resistor element and its resistance value changes with temperature much less than the resistance of the connection element. A voltage tap positioned in the region of these equipotential lines on the connection element experiences a smaller change in electrical potential with a change in temperature than a voltage tap not positioned in the region of these equipotential lines. In particular, in the described resistor arrangement, the influence of temperature on the measurement signal detected at such a voltage tap is much smaller than in a resistor arrangement in which the current flow lines are not deflected at the transition from a connection element to a resistor element.

The described effect is outwardly effective and thus technically usable if the deflection of the current flow lines does not only occur as an edge effect in edge regions of the contact faces, but if the deflection of the current flow lines has occurred substantially over the entire extent of the contact face. The deflection of the current flow lines must therefore be averaged over the entire contact face by an angle of at least 5°.

In a preferred embodiment of the invention, the at least one resistor element can be arranged in such a way that the current flow lines are deflected by an angle of at least 15°, preferably at least 25° and by at most 60°. If the current flow lines are deflected by at least 15°, then the influence of the temperature on the measurement signal is particularly small. Deflections of more than 60° are difficult to achieve by design.

Within the scope of one embodiment, the connection elements and the at least one resistor element can be arranged in such a way that, when current flows through the resistor arrangement, current flow lines are formed which are deflected at both contact sides of the resistor element by the same angle, averaged over the particular entire contact face, but in mutually opposite directions, at the transition from the particular connection element to the resistor element, i.e. when passing through the particular contact face. The current flow lines are thus deflected at the second contact side of the resistor element by the same angular amount as at the first contact side of the resistor element, but in opposite directions, i.e. in opposite orientation of the angle. The angles have different signs. The deflection at the second contact side is in a second direction, which is opposite to the first direction in which the current flow lines at the first contact side of the resistor element are deflected. By deflecting the current flow lines twice by the same angle but in opposite directions, the direction of the current in the connection elements is the same. The distribution of the current flow lines is quasi point symmetrical around the geometric center of the resistor element. Such a resistor arrangement is particularly suitable for monitoring a current storage device of a motor vehicle.

Within the scope of a further embodiment, the resistor arrangement may have, in the plane which is perpendicular to the direction of the smallest spatial extent of the resistor arrangement, a base area which corresponds substantially to a parallelogram, in particular a rectangle, the parallelogram having a first and a second longitudinal side which are substantially parallel to the direction of the current in the connection elements, and the contact sides of the at least one resistor element or their respective extensions may form an angle of at least 25° and at most 85° with the longitudinal sides of the parallelogram. The fact that the base area of the resistor arrangement corresponds substantially to a parallelogram means that opposite sides of the base area are parallel to each other. The base area of the resistor arrangement may deviate from the shape of a geometrically ideal parallelogram, for example, in that the corners of the resistor arrangement are rounded or chamfered or in that the outer contour of the resistor arrangement has recesses or projections at some points. In particular, the base area of the resistor arrangement may be substantially rectangular in shape. The contact sides of the resistor element are inclined with respect to the outer contour of the resistor arrangement, and they form an angle of at least 25° and at most 85° with the longitudinal sides of the parallelogram. The resistor element is thus not arranged perpendicularly relative to the direction of current flow, which results substantially from the position of the connection elements, but is arranged obliquely, the deviation relative to the perpendicular arrangement being at least 5° and at most 65°. Due to this oblique arrangement, the current flow lines are each deflected by an angle of at least 5° when passing from the connection element to the resistor element, i.e. substantially when passing through the contact faces between the resistor element and the connection elements. Preferably, the contact sides of the resistor element form an angle of at least 40° and at most 75°, particularly preferably at most 65°, with the outer contour of the resistance arrangement defined by the longitudinal sides of the parallelogram. In this case, the deviation from the right-angled arrangement is at least 15°, particularly preferably at least 25°, and at most 50°.

Within the scope of a particular variant of this embodiment, on at least one of the connection elements there can be provided at least one voltage tap positioned on a face enclosed by a right-angled triangle, the hypotenuse of which comprises or is a contact side of the resistor element, the first leg of which is a portion of the first longitudinal side of the parallelogram, and the second leg of which is formed by a perpendicular dropped onto the first longitudinal side of the parallelogram from the point of intersection of the hypotenuse with the second longitudinal side of the parallelogram. In the face defined in this way, equipotential lines are formed when current flows, which intersect the contact sides of the resistor element and therefore shift very little when the temperature changes. A voltage tap positioned there thus detects a voltage signal that is hardly influenced by the temperature dependence of the resistivity of the material of the connection element.

Within the scope of a particular variant of this embodiment, the voltage tap may be positioned on an area enclosed by a right-angled triangle of which the hypotenuse comprises or is a portion of a contact side of the resistor element, the first leg of which is a portion of the first longitudinal side of the parallelogram, and the second leg of which is formed by a perpendicular dropped onto the first longitudinal side of the parallelogram from a point of the hypotenuse located centrally between the two longitudinal sides of the parallelogram. This triangle defined in this way is a partial triangle of the triangle defined above. In this partial triangle, equipotential lines are formed when current flows, and these lines shift particularly little when the temperature changes. When the voltage tap is positioned in this partial triangle, it detects a voltage signal which is therefore affected particularly little by the temperature dependence of the resistivity of the material of the connection element.

Within the scope of a further variant of this embodiment, at least one voltage tap may be present on each of two connection elements, and at least two voltage taps may be arranged point-symmetrically with respect to one another. In this case, the center of symmetry is defined by a point which is equidistant from both longitudinal sides of the parallelogram and which lies on an imaginary line running equidistantly between the two contact sides of the resistor element. The center of symmetry thus corresponds to the geometric center of the resistor element, if any recesses on its edges are disregarded. Investigations have shown that with such a pair of voltage taps a voltage signal can be acquired which is hardly influenced by the temperature dependence of the resistivity of the material of the connection elements.

Within the scope of an additional embodiment, the connection elements may have means for connecting the resistor arrangement to an external circuit, so that a main current direction in the resistor arrangement can be defined by these means, and the contact sides of the resistor element may form an angle of at most 85° with the main current direction. By the means for connecting the resistor arrangement to an external circuit, the inclination of the resistor element with respect to the main current direction can be defined relatively precisely.

With regard to further technical features and advantages of the resistor arrangement according to the invention, reference is hereby explicitly made to the figures, the figure description, and the exemplary embodiments.

### BRIEF DESCRIPTION OF THE DRAWINGS

Exemplary embodiments of the invention are explained in more detail with reference to the schematic drawings, in which:

FIG. 1 shows a resistor arrangement known from the prior art;

FIG. 2 shows schematically the current lines in the resistor arrangement according to FIG. 1;

FIG. 3 shows schematically the equipotential lines in the resistor arrangement according to FIG. 1;

FIG. 4 shows a resistor arrangement with obliquely positioned resistor element;

FIG. 5 shows schematically the current lines in the resistor arrangement according to FIG. 4;

FIG. 6 shows schematically the equipotential lines in the resistor arrangement according to FIG. 4;

FIG. 7 shows a resistor arrangement with obliquely positioned resistor element and the region for voltage taps;

FIG. 8 shows a resistor arrangement with obliquely positioned resistor element and a preferred region for voltage taps;

FIG. 9 shows a resistor arrangement with obliquely positioned resistor element and a preferred region for voltage taps;

FIG. 10 shows a comparison graph with measurement data; and

FIG. 11 shows a graph with simulation results.

Corresponding parts are provided with the same reference signs in all figures.

### DETAILED DESCRIPTION

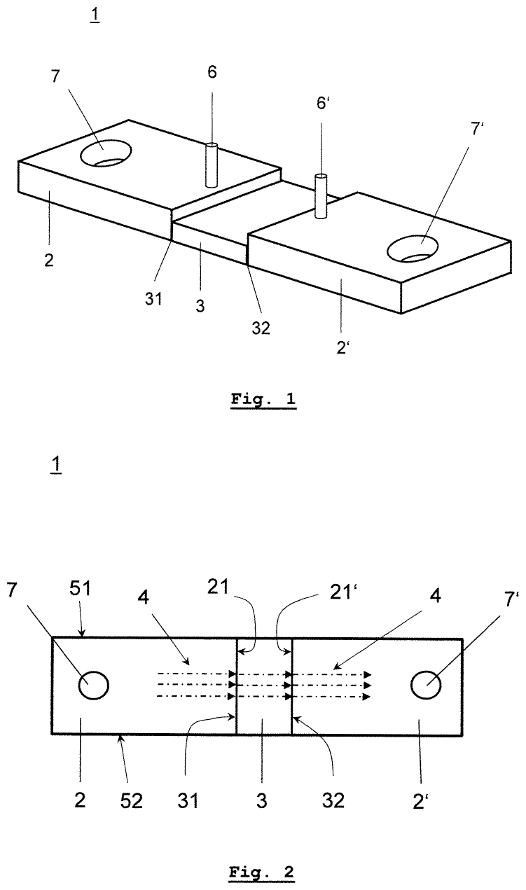

FIG. 1 shows a schematic oblique view of a resistor arrangement 1 known from the prior art. The resistor arrangement 1 has two connection elements 2, 2′ and a resistor element 3 arranged between these connection elements 2, 2′. Both connection elements 2, 2′ each have a hole 7, 7′ by means of which the resistor arrangement 1 can be connected to an external circuit. The resistor element 3 has two contact sides 31, 32, at which it is electrically conductively connected to a corresponding connection element 2, 2′. A voltage tap 6, 6′ is provided on each of the connection elements 2, 2′. When current flows through the resistor arrangement 1, the voltage dropping across the resistor element 3 can be measured via these voltage taps 6, 6′. Because the voltage taps 6, 6′ are not positioned exactly at the contact lines between resistor element 3 and each connection element 2, 2′, the voltage signal also contains contributions caused by the voltage drop in the connection elements 2, 2′.

FIG. 2 shows a plan view of the resistor element 1 according to FIG. 1. The resistor arrangement 1 has a base area in the form of a rectangle with two longitudinal sides 51, 52 parallel to each other. The resistor element 3 is arranged so that its two contact sides 31, 32 are perpendicular to the two longitudinal sides 51, 52 of the rectangle. The current flow lines 4 representing the path of the current through the resistor arrangement 1 are shown schematically by dash-dot arrows. The current flow lines 4 run parallel to the two longitudinal sides 51, 52 of the resistor arrangement both in the connection elements 2, 2′ and in the resistor element 3. The current flow lines 4 are perpendicular to the contact faces 21, 21′ of the two connection elements 2, 2′. When the current passes through the contact faces 21, 21′, i.e. at the transition from one connection element 2, 2′ to the resistor element 3 in each case, the current does not change its direction. The current flow lines 4 are not deflected.

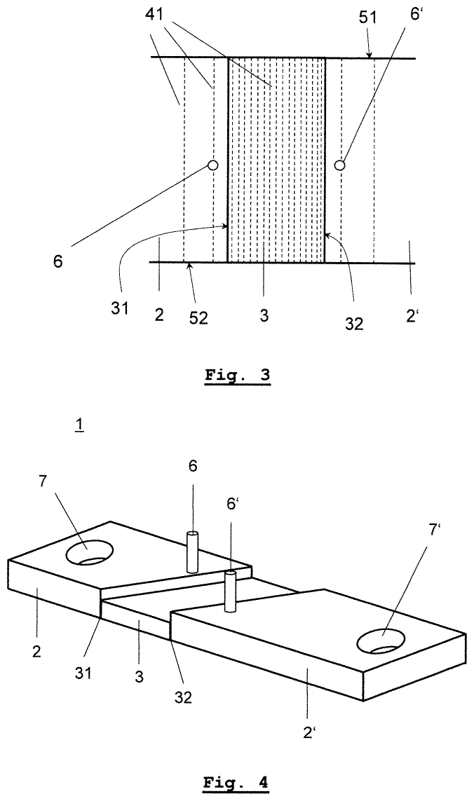

FIG. 3 schematically shows the equipotential lines 41 that result when current flows through the resistor arrangement 1 according to FIG. 1 and FIG. 2. The equipotential lines 41 run both in the connection elements 2, 2′ and in the resistor element 3 parallel to the contact faces 31, 32 of the resistor element 3 and perpendicular to the longitudinal sides 51, 52 of the resistor arrangement 1. Consequently, the equipotential lines 41 in the connection elements 2, 2′ do not intersect the contact faces 31, 32 of the resistor element 3. In the resistor element 3, the equipotential lines 41 are significantly denser than in the connection elements 2, 2′ due to the greater resistance. If the temperature of the resistor arrangement 1 changes, the equipotential lines 41 in the connection elements 2, 2′ shift predominantly because the resistivity of the material of the connection elements 2, 2′ is dependent more strongly on the temperature than the resistivity of the material of the resistor element 3. A changed voltage is therefore detected via the two voltage taps 6, 6′ for the same current strength.

FIG. 4 schematically shows an oblique view of a resistor arrangement 1 in which the resistor element 3 is arranged obliquely between the two connection elements 2, 2′. The resistor element 3 has two contact sides 31, 32 at which it is electrically conductively connected to respective connection elements 2, 2′. Both connection elements 2, 2′ each have a hole 7, 7′ by means of which the resistor arrangement 1 can be connected to an external circuit. A main current direction can be defined through these bores 7, 7′ by mentally connecting the respective centers of the two bores by a line. The contact sides 31, 32 of the resistor element 3 are inclined with respect to this main current direction. A voltage tap 6, 6′ is provided on each of the connection elements 2, 2′. As in the prior art resistor arrangement 1, the voltage taps 6, 6′ are not positioned exactly at the contact line between resistor element 3 and each connection element 2, 2′, but at a distance from the resistor element 3.

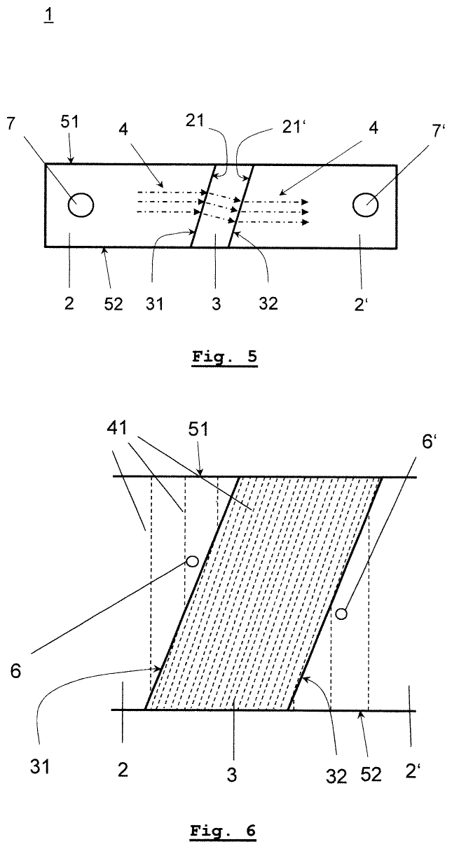

FIG. 5 shows a plan view of the resistor element 1 according to FIG. 4. The resistor arrangement 1 has a base area in the form of a rectangle with two parallel longitudinal sides 51, 52. The resistor element 3 is arranged so that it forms an angle of approximately 70° with the longitudinal sides 51, 52. The current flow lines 4, which represent the path of the current through the resistor arrangement 1, are shown schematically by dash-dot arrows. The current flow lines 4 run parallel to the two longitudinal sides 51, 52 of the resistor arrangement 1 only in the connection elements 2, 2′. In the resistor element 3, the current flow lines 4 run approximately perpendicular to the contact sides 31, 32 of the resistor element 3 and thus run at an angle with respect to the longitudinal sides 51, 52 of the resistor arrangement 1. When passing through the respective contact faces 21, 21′ of the two connection elements 2, 2′, i.e. at the transition from one connection element 2, 2′ to the resistor element 3 in each case, the current flow lines 4 are thus deflected by approximately 20° in each case. The deflection takes place at the second contact face 21′ in the opposite direction compared to the deflection at the first contact face 21, so that the direction of the current flow lines 4 is the same in both connection elements 2, 2′.

FIG. 6 schematically shows the equipotential lines 41 that result when current flows through the resistor arrangement 1 according to FIG. 4 and FIG. 5. As in the case of the resistor arrangement known from the prior art, the equipotential lines 41 in the resistor element 3 are significantly denser than in the connection elements 2, 2′ due to the greater resistance. In the two connection elements 2, 2′, the equipotential lines 41 run substantially perpendicularly to both longitudinal sides 51, 52 of the resistor arrangement 1. In the resistor element 3, the equipotential lines 41 run almost parallel to the contact faces 31, 32 of the resistor element 3. They are inclined only by an angle of less than 5° with respect to the contact faces 31, 32. Due to this inclination, equipotential lines 41 running close to the contact faces 31, 32 of the resistor element 3 intersect these contact faces 31, 32 and then continue in the region of the connection elements 2, 2′ as described above. Two voltage taps 6, 6′ are positioned in this region of the two connection elements 2, 2′.

FIG. 7 schematically shows a plan view of the resistor arrangement 1 according to FIGS. 4 to 6. On both sides of the resistor element 3, two right-angled triangles are drawn in hatched lines, in which the voltage taps 6, 6′ can be positioned to take advantage of the effect described above. The voltage taps 6, 6′ are positioned close to the resistor element 3. The two voltage taps 6, 6′ are arranged point-symmetrically with respect to each other. The center of symmetry is located in the geometric center of the resistor element 3 and is marked by a cross.

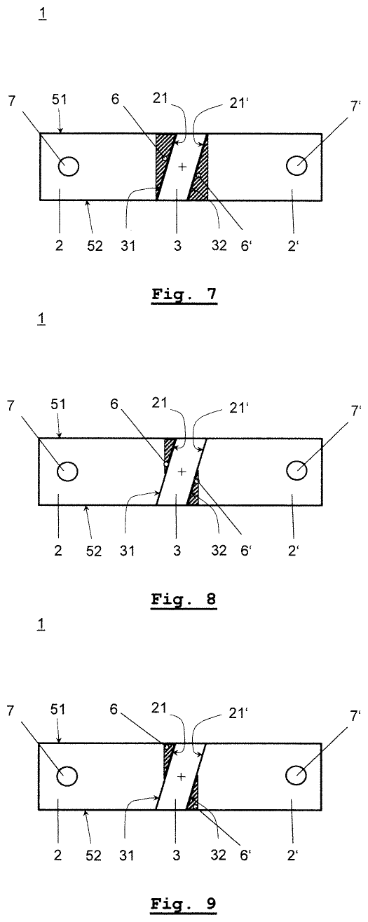

FIG. 8 shows a schematic plan view of the resistor arrangement 1 according to FIGS. 4 to 6. On both sides of the resistor element 3, two right-angled triangles are drawn in hatched lines, in which the voltage taps 6, 6′ can preferably be positioned in order to make particularly good use of the effect described above. The voltage taps 6, 6′ are positioned close to the resistor element 3. The two voltage taps 6, 6′ are arranged point-symmetrically with respect to each other. The center of symmetry is located in the geometric center of the resistor element 3 and is marked by a cross.

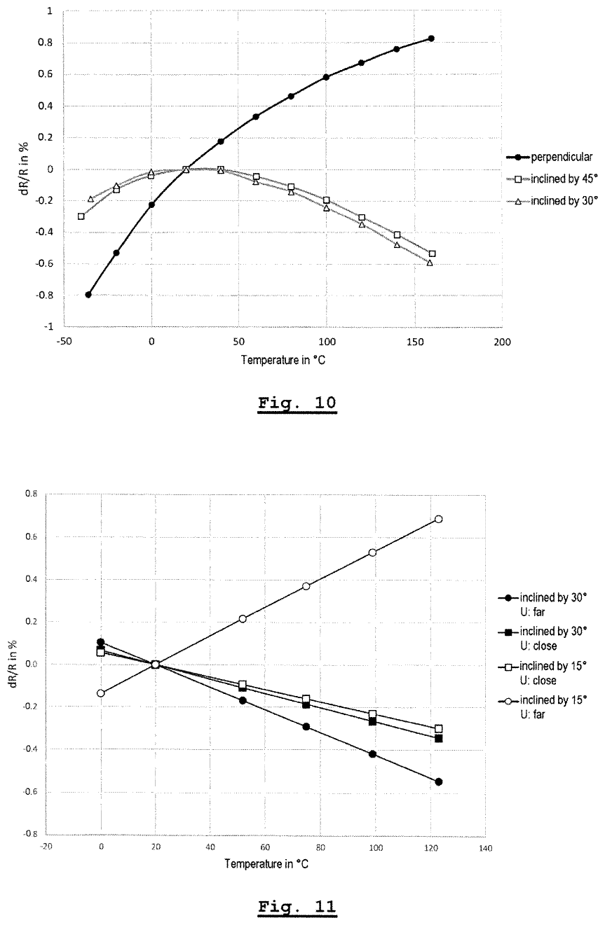

FIG. 9 schematically shows a plan view of a resistor arrangement 1 similar to FIG. 8. In the case of FIG. 9, the voltage taps 6, 6′ are positioned at a clear distance from the resistor element 3 at the outer edge near each of the longitudinal sides 51, 52 of the resistor arrangement 1 in the preferred region.

FIG. 10 shows a graph in which the measured relative resistance change dR/R in % is plotted as a function of temperature for three resistor arrangements (TCR curve). The resistance was measured using a measuring bridge in the four-wire method. The resistance at 20° C. was used as the reference value in each case. The data series, labeled “perpendicular” was recorded on a resistor arrangement as shown in FIGS. 1 to 3. The voltage taps 6, 6′ were positioned as shown schematically in FIG. 1 and FIG. 3. At a temperature of 100° C., the measured resistance is 0.6% greater than the resistance at 20° C., and at 150° C. the change is about 0.8%. The data series labeled “inclined by 45°” was recorded on a resistor arrangement similar to the resistor arrangement 1 shown in FIGS. 4 to 6, where the resistor element 3 was inclined by 45° with respect to the resistor element 3 of the resistor arrangement 1 shown in FIGS. 1 to 3. The voltage taps 6, 6′ were positioned as shown schematically in FIG. 4 and FIG. 6. At a temperature of 100° C., the measured resistance is 0.2% lower than the resistance at 20° C., and at 150° C. the change is less than −0.5%. The fact that the measured resistance appears to decrease with temperature can be explained by a corresponding shift in the equipotential lines for the resistor arrangement with inclined resistor element. The data series labeled “tilted by 30°” was recorded on a resistor arrangement similar to the resistor arrangement 1 shown in FIGS. 4 to 6, wherein the resistor element 3 was tilted by 30° with respect to the resistor element 3 of the resistor arrangement 1 shown in FIGS. 1 to 3. The voltage taps 6, 6′ were positioned as shown schematically in FIG. 4 and FIG. 6. At a temperature of 100° C., the measured resistance is 0.25% lower than the resistance at 20° C., and at 150° C. the change is slightly more than −0.5%. The comparison of the measured data shows that, for the resistor arrangements with inclined resistor element, especially in the temperature range between 0° C. and 100° C., the change of the measured resistance with temperature is significantly lower than for the resistor arrangement known from the prior art. This proves the advantage of the proposed resistor arrangement.

FIG. 11 shows a graph with results of simulation calculations. The calculated relative resistance change dR/R as a function of temperature is plotted for two other resistor arrangements. The data series labeled “inclined by 30°” were calculated for a resistor arrangement similar to the resistor arrangement shown in FIGS. 4 to 6, where the resistor element 3 was inclined by 30° with respect to the resistor element 3 of the resistor arrangement 1 shown in FIGS. 1 to 3. The data series labeled “inclined by 15°” were calculated for a resistor arrangement similar to the resistor arrangement 1 shown in FIGS. 4 to 6, where the resistor element 3 was inclined by 15° with respect to the resistor element 3 of the resistor arrangement 1 shown in FIGS. 1 to 3. Two pairs of voltage taps 6, 6′ were simulated for each of the two resistor arrangements: a first pair of voltage taps 6, 6′ was simulated as shown in FIG. 8, i.e. positioned close to the resistor element 3. The corresponding data series are labeled “U: close”. A second pair of voltage taps 6, 6′ was simulated as shown in FIG. 9, i.e. positioned close to one each of the longitudinal sides 51, 52 of the resistor arrangement 1, at a distance from the resistor element 3. The associated data series are marked with the designation “U: far”. In contrast to the experimentally determined data (FIG. 10), the calculated data lie on a straight line, while the data series of the experimentally determined data each have a curvature. This curvature may be due to effects caused by the weld seam.

For both simulated resistor arrangements, the voltage taps positioned close to the resistor element give almost the same change in resistance with temperature. At 100° C., the relative change with respect to the resistor value at 20° C. is approximately −0.2%. This result agrees well with the measured data. The fact that the simulated resistance appears to decrease with temperature can be explained by a corresponding shift in the equipotential lines.

The data obtained for voltage taps positioned far from the resistor element in each case show significantly different behavior for the two simulated resistor arrangements: The data obtained on the resistor arrangement with the resistor element inclined by 15° show a positive slope, i.e., an increase in resistance with temperature, and are approximately on par with the measured data obtained experimentally on the prior art resistor arrangement; see FIG. 10. The data obtained on the resistor arrangement with the resistor element inclined by 30° show a negative slope, i.e., an apparent decrease in resistance with temperature. The decrease in this case is greater than the decrease in resistance when the voltage taps are positioned close to the resistor element. Comparison of the data suggests that, for a given slope of the resistor element in combination with a given position of the voltage taps, opposing effects can cancel each other out and thus the voltage measurement is based on an apparent resistance that is practically independent of temperature.

### LIST OF REFERENCE SIGNS

1 resistor arrangement
2, 2′ connection element
21, 21′ contact face
3 resistor element
31 contact side
32 contact side
4 current flow lines
41 equipotential lines
51 longitudinal side
52 longitudinal side
6, 6′ voltage tap
7, 7′ connection means, bore

1. A resistor arrangement for measuring the strength of an electric current flowing through the resistor arrangement, the resistor arrangement comprising at least two strip- or plate-shaped connection elements for connecting the resistor arrangement to an external circuit and at least one strip- or plate-shaped resistor element arranged between the connection elements with respect to the direction of the current, the connection elements and the resistor element for forming the resistor arrangement being arranged in a plane next to each other and in a row with respect to each other in such a way that the resistor arrangement has the form of a strip and has its smallest spatial extent in a direction oriented perpendicular to the direction of the electric current, the at least one resistor element consisting of a material of which the electrical resistivity at room temperature is greater by at least a factor of 10 than the electrical resistivity of the material of the connection elements, the at least one resistor element having two contact sides parallel to each other, and the connection elements, each having a contact face at which they are connected to one of the contact sides of the at least one resistor element or of a further resistor element and are in electrical contact, wherein the at least one resistor element is arranged in such a way that, when current flows through the resistor arrangement, current flow lines are formed which are deflected at at least one of the contact sides of the resistor element by an angle of at least 5°, averaged over the entire contact face, at the transition from the connection element to the resistor element, this deflection taking place in a plane which is perpendicular to the direction of the smallest spatial extent of the resistor arrangement.

2. The resistors arrangement according to claim 1, wherein the connection elements and the at least one resistor element are arranged in such a way that the current flow lines are deflected by an angle of at least 15° and by at most 60°.

3. The resistor arrangement according to claim 1, wherein the at least one resistor element is arranged in such a way that, when current flows through the resistor arrangement, current flow lines are formed which are deflected at both contact sides of the resistor element by the same angle, averaged over the particular entire contact face, but in mutually opposite directions, at the transition from the particular connection element to the resistor element.

4. The resistor arrangement according to claim 1, whereinthe resistor arrangement has, in the plane which is perpendicular to the direction of the smallest spatial extent of the resistor arrangement, a base area which corresponds substantially to a parallelogram, the parallelogram having a first and a second longitudinal side which are parallel to the direction of the current in the connection elements, and the contact sides of the at least one resistor element form an angle of at least 25° and at most 85° with the longitudinal sides of the parallelogram.

5. The resistor arrangement according to claim 4, wherein on at least one of the connection elements there is provided at least one voltage tap positioned on an area enclosed by a right-angled triangle, the hypotenuse of which comprises or is a contact side of the resistor element, the first leg of which is a portion of the first longitudinal side of the parallelogram, and the second leg of which is formed by a perpendicular dropped onto the first longitudinal side of the parallelogram from the point of intersection of the hypotenuse with the second longitudinal side of the parallelogram.

6. The resistor arrangement according to claim 5, wherein the voltage tap is positioned on an area enclosed by a right-angled triangle, the hypotenuse of which comprises or is a portion of a contact side of the resistor element, the first leg of which is a portion of the first longitudinal side of the parallelogram, and the second leg of which is formed by a perpendicular dropped onto the first longitudinal side of the parallelogram from a point of the hypotenuse located centrally between the two longitudinal sides of the parallelogram.

7. The resistor arrangement according to claim 5, wherein at least one voltage tap is present on each of the two connection elements, and at least two voltage taps are arranged point-symmetrically with respect to one another, the center of symmetry being defined by a point which is equidistant from both longitudinal sides of the parallelogram and which lies on an imaginary line running equidistantly between the two contact sides, of the resistor element.

8. The resistor arrangement according to claim 1, wherein the connection elements have means for connecting the resistor arrangement to an external circuit, so that a main current direction in the resistor arrangement is defined by these means, and in that the contact sides of the resistor element form an angle of at most 85° with the main current direction.
